(19) United States
(12) Patent Application Publication
(10) Pub. No.: US 2014/0262450 A1
(43) Pub. Date: Sep. 18, 2014

(54) Multilayer Printed Circuit Board Structure

(71) Applicant: Yun-Chao YEH, (US)

(72) Inventors: Yun-Chao YEH, Tao-Yuan County (TW); Han-Shiang HUAG, Tao-Yuan County (TW); Yu-Ying MA, Tao-Yuan County (TW)

(21) Appl. No.: 13/940,144

(22) Filed: Jul. 11, 2013

(30) Foreign Application Priority Data
Mar. 13, 2013 (TW) 102108876

(51) Int. Cl. H05K 1/02

(52) U.S. Cl. CPC H05K 1/0298
USPC 174/252

(57) ABSTRACT

A multilayer printed circuit board structure is formed by stacking an aluminum foil substrate, a first pre-impregnated body, an aluminum foil middle layer, a second pre-impregnated body and a copper foil surface layer sequentially. Both the first pre-impregnated body and the second pre-impregnated body are composed by a fiber cloth impregnated with a heat conduction material in order that the heat conduction material can fill up the gaps of the fiber cloth. The heat conduction material is mixed from at least a resin and a filling material.

### BACKGROUND OF THE INVENTION

1. Field of Invention

The present invention relates to a multilayer printed circuit board structure and more particularly to a multilayer printed circuit board structure which is specially suitable for using in light emitting diode base plate and combined by stacking an aluminum foil substrate, a first pre-impregnated body, an aluminum foil middle layer, a second pre-impregnated body and a copper foil surface layer as well as composed of a resin in order to feature the advantages of excellent thermal conductivity, low hygroscopicity, excellent heat resistance, high melting point, low dielectric constant and low dielectric loss coefficient, and the printed circuit board is not easy to crack.

2. Related Art

In the recent years, the development trends for electronic instrument are higher functions, lighter weight, thinner thickness, shorter dimensions and smaller size. Advancements such as more number of layers, thinner insulating layer and higher density have been accomplished for printed wiring board. Therefore, the quality of materials for composing printed wiring board has to be strengthened in terms of hygroscopicity, heat resistance, stability in large dimensions and long-term insulating property.

Currently, printed circuit board is usually prepared by impregnating a textile fabric with a liquid epoxy resin. In order to meet the development trend of thinner printed wiring board used in electronic instrument with higher functions, lighter weight, thinner thickness, shorter dimensions and smaller size, light weight glass fiber cloth is mainly used as a substrate for preparing a pre-impregnated body. In the production of a conventional multilayer circuit board, a copper foil base plate has to undergo blackening in order to roughen two copper foil sides of the copper foil base plate. Then, one of the copper foil sides is disposed with a resin glass fiber cloth and another layer of copper foil. Lastly, the copper foil base plate, the resin glass fiber cloth and the other layer of copper foil are laminated to produce a circuit board with multilayer copper foils.

However, in the above mentioned production method for processing and producing the circuit board, besides the high cost of copper foils, the adhering area of the pre-impregnated material is often reduced after pre-impregnation. Consequently, the viscosity, heat conductivity and moisture resistance are reduced, and the circuit board is easy to crack in assembling.

### SUMMARY OF THE INVENTION

A primary objective of the present invention is to provide a low cost multilayer printed circuit board structure with excellent thermal conductivity, low hygroscopicity, excellent heat resistance, high melting point, low dielectric constant and low dielectric loss coefficient, and the printed circuit board is not easy to crack.

In order to achieve the above-mentioned objective, the multilayer printed circuit board structure provided by the present invention is formed by stacking an aluminum foil substrate, a first pre-impregnated body, an aluminum foil middle layer, a second pre-impregnated body and a copper foil surface layer sequentially. Both the first pre-impregnated body and the second pre-impregnated body are composed by a fiber cloth impregnated with a heat conduction material in order that the heat conduction material can fill up the gaps of the fiber cloth. The heat conduction material is mixed from at least a resin and a filling material.

When the multilayer printed circuit board structure of the present invention is embodied, the fiber cloth is woven from 15 to 25 counts of warps and 15 to 25 counts of wefts. The fiber cloth is glass fiber cloth, quartz fiber, nylon fiber, cotton yarn fiber or hybrid fiber.

When the multilayer printed circuit board structure of the present invention is embodied, the filling material is, for examples, aluminum oxide, aluminum nitride, magnesium oxide, boron nitride, aluminum hydroxide or magnesium hydroxide.

When the multilayer printed circuit board structure of the present invention is embodied, the resin is a resin mixed with phenol. The resin is selected from one of phenolic aldehyde resin, cresol phenolic aldehyde resin, naphthol aralkyl resin, triphenol methane resin, terpene modified phenol resin, bicyclopentadiene modified phenol resin and phenol aralkyl resin with benzene skeleton, or is a mixture of any two of the above.

When the multilayer printed circuit board structure of the present invention is embodied, the resin is a perfluoro-thermoplastic resin or an aralkyl epoxy resin with low hygroscopicity and high heat resistance.

When the multilayer printed circuit board structure of the present invention is embodied, the resin is an epoxy resin mixed with a phenol addition product of a conjugated diolefine hydrocarbon polymer.

When the multilayer printed circuit board structure of the present invention is embodied, in the heat conduction material of the first pre-impregnated body, the filling material is accounted for 1% to 80%, the resin is accounted for 20% to 99%; in the heat conduction material of the second pre-impregnated body, the filling material is accounted for 1% to 70%, the resin is accounted for 30% to 99%.

The present invention will become more fully understood by reference to the following detailed description thereof when read in conjunction with the attached drawings.

### BRIEF DESCRIPTION OF THE DRAWINGS

FIG. 1 is a perspective view of a multilayer printed circuit board structure according to an embodiment of the disclosure.

### DETAILED DESCRIPTION OF THE INVENTION

Please refer to FIG. 1. FIG. 1 is a perspective view of a multilayer printed circuit board structure according to an embodiment of the disclosure. The multilayer printed circuit board structure is composed of an aluminum foil substrate 1, a first pre-impregnated body 2, an aluminum foil middle layer 3, a second pre-impregnated body 4 and a copper foil surface layer 5.

Please refer to FIG. 1. The first pre-impregnated body 2 is combined on the aluminum foil substrate 1; the aluminum foil middle layer 3 is combined on the first pre-impregnated body 2, the second pre-impregnated body 4 is combined on the aluminum foil middle layer 3; and the copper foil surface layer 5 is combined on the second pre-impregnated body 4.

Both the first pre-impregnated body 2 and the second pre-impregnated body 4 are composed by a fiber cloth impregnated with a heat conduction material. Preferably, a thickness of the first pre-impregnated body 2 is larger than that of the second pre-impregnated body 4. The fiber cloth is woven from 15 to 25 counts of warps and 15 to 25 counts of wefts. The fiber cloth is glass fiber cloth, quartz fiber, nylon fiber, cotton yarn fiber or hybrid fiber in order that the heat conduction material can fill up the gaps of the fiber cloth.

The heat conduction material is mixed from at least a resin and a filling material. Practically, the filling material and the resin in the heat conduction material can be mixed with proportions based on requirements. For examples, the same mixture proportions allow the heat conduction material in the first pre-impregnated body 2 and the second pre-impregnated body 4 to have the same proportion; or, the filling material and the resin are mixed with different proportions. For example, in the heat conduction material of the first pre-impregnated body 2, the filling material is accounted for 1% to 80%, the resin is accounted for 20% to 99%; in the heat conduction material of the second pre-impregnated body 4, the filling material is accounted for 1% to 70%, the resin is accounted for 30% to 99%; in order that the intensity of heat conduction of the second pre-impregnated body 4 is larger than that of the first pre-impregnated body 2.

The filling material is, for examples, aluminum oxide, aluminum nitride, magnesium oxide, boron nitride, aluminum hydroxide or magnesium hydroxide, in order that the gaps can be filled and leveled up. Thereby, the viscosity and dielectric strength can be enhanced, and the problems of cracking and detachment of circuit board and poor heat conductivity can be prevented from happening easily. In addition, because the glass fiber cloth is woven from 15 to 25 counts of warps and 15 to 25 counts of wefts, the gaps between the warps and wefts are provided for more of the heat conduction material to be able to integrate in the glass fiber cloth during the pre-impregnation. Therefore, after the lamination, the viscosity and heat conduction effects of the overall structure can be enhanced due to the increase in the combined area of the heat conduction material. Thereby, the heat dissipation and reliability of electronic products can be enhanced substantially when the multilayer printed circuit board structure is applied in LED devices and loading systems which require outstanding heat conductivity.

The resin in the heat conduction material in this embodiment is a resin mixed with phenol in order to achieve the outstanding effects of low elasticity and low hygroscopicity in high temperatures. The resin is selected from one of phenolic aldehyde resin, cresol phenolic aldehyde resin, naphthol aralkyl resin, triphenol methane resin, terpene modified phenol resin, bicyclopentadiene modified phenol resin and phenol aralkyl resin with benzene skeleton, or is a mixture of any two of the above. Preferably, select the ones with low viscosity.

Or, the resin is a perfluoro-thermoplastic resin or an aralkyl epoxy resin with low hygroscopicity and high heat resistance. The perfluoro-thermoplastic resin, for examples, is polytetrafluoroethylene; tetrafluoroethylene and hexafluoropropene, vinyl ether, ethylene; poly-(ether-ether-ketone); poly-(ether-ketone-ketone); and poly-(ether-ketone); polyester such as poly-(ethylene terephthalate), poly-(ethylene 2,6-naphthalate), and polyester formed from bisphenol A and isophthalic acid/terephthalic acid; polycarbonate especially with high glass transition temperature; poly 4-methylpentene; poly-(aryl sulphides); poly-(ether-imid); poly-(aryl ether); preferably, perfluoro-polymer in order that it has low hygroscopicity, high melting point, low dielectric constant and low dielectric loss coefficient. The aralkyl epoxy resin is preferably a biphenyl epoxy resin in order to enhance the moisture resistance and to achieve outstanding heat resistance.

Thereby, when the above composed structure is applied in a light emitting diode and after a light emitting diode wiring is fixed on the copper foil surface layer 5, the heat of the copper foil surface layer 5 can be speedily conducted to the aluminum foil middle layer 3 for dissipation through the second pre-impregnated body 4. The heat is then conducted to the first pre-impregnated body 2 and the aluminum foil substrate 1. Besides that the effects of heat conduction and heat dissipation can be achieved, the requirements for thickness and strength can also be met.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

What is claimed is:

1. A multilayer printed circuit board structure, comprising:
an aluminum foil substrate;
a first pre-impregnated body combined on the aluminum foil substrate;
an aluminum foil middle layer combined on the first pre-impregnated body;
a second pre-impregnated body combined on the aluminum foil middle layer;
a copper foil surface layer combined on the second pre-impregnated body;
wherein, both the first pre-impregnated body and the second pre-impregnated body are composed by a fiber cloth impregnated with a heat conduction material in order that the heat conduction material can fill up the gaps of the fiber cloth, the heat conduction material is mixed from at least a resin and a filling material.

2. The multilayer printed circuit board structure as claimed in claim 1, wherein the fiber cloth is woven from 15 to 25 counts of warps and 15 to 25 counts of wefts.

3. The multilayer printed circuit board structure as claimed in claim 2, wherein the fiber cloth is glass fiber cloth, quartz fiber, nylon fiber, cotton yarn fiber or hybrid fiber.

4. The multilayer printed circuit board structure as claimed in claim 1, wherein the filling material is, for examples, aluminum oxide, aluminum nitride, magnesium oxide, boron nitride, aluminum hydroxide or magnesium hydroxide.

5. The multilayer printed circuit board structure as claimed in claim 1, wherein the resin is a resin mixed with phenol, the resin is selected from one of phenolic aldehyde resin, cresol phenolic aldehyde resin, naphthol aralkyl resin, triphenol methane resin, terpene modified phenol resin, bicyclopentadiene modified phenol resin and phenol aralkyl resin with benzene skeleton, or is a mixture of any two of the above.

6. The multilayer printed circuit board structure as claimed in claim 1, wherein the resin is a perfluoro-thermoplastic resin or an aralkyl epoxy resin with low hygroscopicity and high heat resistance.

7. The multilayer printed circuit board structure as claimed in claim 1, wherein the resin is an epoxy resin mixed with a phenol addition product of a conjugated diolefine hydrocarbon polymer.

8. The multilayer printed circuit board structure as claimed in claim 1, wherein in the heat conduction material of the first pre-impregnated body, the filling material is accounted for 1% to 80%, the resin is accounted for 20% to 99%, in the heat conduction material of the second pre-impregnated body, the filling material is accounted for 1% to 70%, the resin is accounted for 30% to 99%.
